(19) United States
(12) Patent Application Publication
(10) Pub. No.: US 2024/0387202 A1
(43) Pub. Date: Nov. 21, 2024

(54) DEVICE AND METHOD FOR BONDING

(71) Applicant: EV Group E. Thallner GmbH, St. Florian am Inn (AT)

(72) Inventor: Andreas Fehkuhrer, St. Florian am Inn (AT)

(73) Assignee: EV Group E. Thallner GmbH, St. Florian am Inn (AT)

(21) Appl. No.: 18/689,465

(22) PCT Filed: Nov. 8, 2021
(86) PCT No.: PCT/EP2021/080886

§ 371 Date: Mar. 6, 2024

(51) Int. Cl. H01L 21/67

(52) U.S. Cl. CPC H01L 21/67092

(57) ABSTRACT

The present invention relates to a device for bonding a first substrate with a second substrate, comprising at least one deformation device for deforming at least one of the two substrates by means of a fluid, wherein the at least one deformation device is mobile. Moreover, the invention relates to a corresponding method.

### FIELD OF THE INVENTION

The invention relates to a device and a method for bonding substrates according to the independent claims.

### BACKGROUND OF THE INVENTION

There are a number of methods in the semiconductor industry for aligning and connecting (bonding) two, in particular, structured substrates together. Fusion bonding or a fusion bonder is understood to mean a device, which produces bonding of two substrates by, in particular, central contacting with the aid of an actuator, in particular a pin. Self-fixing occurs on account of the adhesive forces between the substrate surfaces.

If the fixing is for a limited time or if the fusion bond has not yet undergone any heat treatment, this is referred to as prebonding. A prebond can in the broadest sense also be regarded as a temporary bond, since it is reversible, i.e. since the substrates can be separated from one another again without damage. In the following text, the words bonding, temporary bonding and prebonding are used synonymously.

The following methods or devices are known in the prior art.

A mechanical pin capable of being moved in translation is disclosed in publication EP 3005407B1. However, it is a disadvantage that the pin not only exerts forces on the substrate normal to the substrate surface, but also parallel to the substrate surface.

In publication WO 2013/023708A1, a fixed nozzle is used which does not permit any essential control options. In publication EP2351076B1, a pressurised gas flow through a channel is disclosed. Here too, however, no essential options are provided for the control, so that considerable drawbacks arise in the bonding accuracy.

One of the greatest technical problems in joining two substrates is represented by the alignment accuracy of functional units between the substrates. Although the substrates can be aligned very precisely with one another by alignment systems, distortions of the substrates can occur during the bonding process. As a result of the distortions thus arising, the functional units are disadvantageously not aligned correctly with one another at all positions. The alignment inaccuracy at a specific point on the substrate may be a result of a distortion, a scaling error, or for example a lens fault in a lithographic device which has been used for the generation of the structure. All the subject areas which deal with such problems or errors are grouped together under the term “overlay” errors.

It is the aim of the present invention, therefore, to remove or at least considerably reduce the drawbacks described above. These problems are solved with the subject-matter of the invention. Advantageous developments of the invention are specified in the sub-claims. All combinations of at least two of the features stated in the description, in the claims and/or the figures also fall within in the scope of the invention. In the case of stated value ranges, values lying within the stated limits are also disclosed and can be claimed in any combination.

### SUMMARY OF THE INVENTION

The invention relates to a device for bonding a first substrate with a second substrate, comprising at least one deformation device for deforming at least one of the two substrates by means of a fluid, wherein the at least one deformation device is mobile.

The invention also relates to a method for bonding a first substrate with a second substrate, wherein at least one deformation device deforms at least one of the two substrates by means of a fluid, wherein the at least one deformation device is mobile.

In a preferred embodiment, provision is made such that the at least one deformation device comprises a mobile hollow pin, wherein the pin preferably comprises a central axial bore.

In another preferred embodiment, provision is made such that the at least one deformation device comprises a mobile nozzle.

In another preferred embodiment, provision is made such that the at least one deformation device comprises a mobile hose.

In another preferred embodiment, provision is made such that at least one movement device is provided for moving the at least one deformation device.

In another preferred embodiment, provision is made such that the at least one deformation device is arranged in an opening of a substrate mounting fixture.

In another preferred embodiment, provision is made such that the at least one deformation device is mobile or moved normal to the mounting plane of a substrate mounting fixture.

In another preferred embodiment. provision made such that the at least one deformation device is designed for occupying at least one parking position and a working position or that the at least one deformation device occupies at least one parking position and a working position.

In another preferred embodiment, provision is made such that the at least one deformation device is arranged in a parking position completely or at least almost completely in an opening of a substrate mounting fixture.

In another preferred embodiment, provision is made such that the at least one deformation device projects in a maximum position beyond a mounting plane of a substrate mounting fixture.

The two substrates are joined together by the bonding, in particular fusion bonding, advantageously distortion-free and expansion-free as far as possible over the whole area.

In particular, the idea underlying the invention is to make contact between the two substrates in as coordinated a manner and as simultaneously as possible, whereby at least one of the substrates is subjected, before contact is made, to pretensioning, in particular running radially outwards concentrically to centre M of a contact area of the substrate and then only the start of contacting is influenced, whilst after contacting of a section, in particular centre M of the substrate, the substrate is released and on account of its pretensioning bonds automatically with the substrate lying opposite in a controlled manner.

The following text defines that each substrate comprises a bonding side, wherein the bonding sides are bonded together.

The pretensioning is achieved in particular by a deformation, wherein the deformation device acts on the side facing away from the bonding side and the deformation can be controlled by the deformation device.

Deformation is understood in particular to mean a state diverging from an initial state of the substrates. The initial state is for example a curvature set before the contacting of the substrates. The bonding is preferably regulated after contacting of contact surfaces, in particular by controlled regulation of the fixings of the substrates. Suitable fixings or fixing means are especially provided.

The fluid can be a gas, for example N₂ and/or a gas mixture. In a less preferred embodiment. it can be a liquid.

The at least one deformation element preferably comprises a mobile hollow pin. In this case, the fluid can be blown through a hollow channel. The pin constituted hollow comprises for example a central axial bore for the supply of the fluid from a fluid connexion. A fluid feed can take place from outside.

In an alternative embodiment, the at least one deformation device comprises a mobile nozzle. The nozzle can have the same cross-sectional area over its entire length, can become wider, taper or have other complex shapes.

In another alternative embodiment, provision is made such that the at least one deformation device comprises a mobile hose.

In particular, the device comprises at least one movement device (actuator) for moving the at least one deformation device.

By means of a controllable air cushion between the at least one deformation device and the substrate, point-like deformations in particular are reduced and no forces are transferred parallel to the substrate surface onto the substrate. A particularly gentle deformation of the substrate is thus achieved. The particularly gentle deformation of the substrate leads in particular to a reduction of the overlay errors during the bonding process, since a homogeneous force distribution on the substrate reduces local deformations.

A control takes place in particular by means of an, in particular, continuously regulatable adjustment of the distance from the at least one deformation device to the substrate during the deformation and/or by the pressure with which the fluid acts on the substrate.

In particular, by means of the type of nozzle or by the design of the at least one deformation device, an outflow pattern is also changed.

In another preferred embodiment, the fluid is heated or can be heated before and/or while it exits from the at least one deformation device.

In another preferred embodiment the fluid includes a gas mixture, which is fed through a plurality of lines and is mixed in the at least one deformation device and/or is already mixed before entry into the at least one deformation device.

For a given state (e.g. pressure, temperature, Mach number) at the outlet opening of the at least one deformation device. the speed of the fluid diminishes with increasing distance from the substrate surface. The degree of the achievable deformation can thus be controlled.

By means of the controllable air cushion between the at least one deformation device and the substrate, point-like deformations in particular are reduced and no forces are transferred parallel to the substrate surface onto the substrate.

Parameters such as pressure, temperature, force and flow speed are in particular measured and can be controlled separately when required with suitable measurement methods and/or with sensors.

It is particularly advantageous to reduce the so-called effective mounting area of a mounting fixture with the substrate, so that the substrate is supported only partially by the mounting fixture. As a result of the smaller contact area. a lesser degree of adhesion thus results between the substrate and the mounting fixture.

A fixing is fitted in particular, in particular exclusively, in the region of the periphery of the substrate (in particular of the upper substrate), so that an effective fixing is produced with at the same time the smallest possible effective mounting area between a mounting contour of the mounting fixture and the substrate. A gentle and reliable detachment of the substrate is thus possible at the same time, since the detachment forces required for the detachment of the substrate are kept as small as possible.

The at least one deformation device comprises at least one pressure element imposing the mounting contour of the mounting fixture, in order that the pressure can be applied uniformly, in particular from the centre outwards.

The at least one deformation device is preferably designed such that the deformation takes place concentrically with the substrate.

In a less preferred embodiment. the contacting of the two substrates can also take place non-centrally. In the following text of the description, contacting should as a rule be understood to mean central contacting.

The centre is understood in particular to mean the geometrical centre point of a basic ideal body, if necessary compensated for asymmetries. In the case of standard industrial substrates with a notch, the centre is the circle centre-point of the circle which surrounds the ideal substrate without a notch. In the case of standard industrial substrates with a flat side, the centre is the circle centre-point of the circle which surrounds the ideal substrate without a flat side. Analogous considerations apply to arbitrarily formed substrates. In other embodiments, however. it may be useful to understand the centre to be the centre of gravity of the substrate.

In order to guarantee exact, central, point-like contacting, an in particular upper mounting fixture. provided with a central bore and a deformation device which can be moved therein in translation, in particular a nozzle with a fluid line, is preferably equipped with radially symmetric fixings.

The temperature of the fluid and/or of the at least one deformation device can preferably be regulated. By regulating the temperature, local expansions or distortions can be reduced or minimised. As a result of the local thermal influencing, a reduction in the overlay error during bonding can be achieved.

The upper and/or lower mounting fixture can preferably be heated and/or cooled. Temperature sensors enable the measurement and control of the temperature. The signals of the temperature sensors are fed to a temperature regulator, so that the temperature can be regulated as required.

The method according to the invention preferably comprises the following steps, in particular the following sequence:
mounting of a first, upper substrate on a first mounting surface of a first mounting fixture,
mounting of a second, lower substrate on a second mounting surface of a second mounting fixture,
fastening of the substrates on the mounting surfaces by means of fixing elements,
curving of at least one of the contact surfaces of the substrates before contacting the contact surfaces, preferably curving of the fixed upper substrate by means of the at least one deformation device,
in particular, controlled switching-off of the, in particular, upper fixing elements, so that the substrates are joined with one another over the full area.

### Fixing/Fixing Elements

The overlay error is particularly dependent on the type and shape of the substrate mounting fixture and the fixing of the respective substrate. Publication WO2014/191033A1 discloses a plurality of embodiments of preferred substrate mounting fixtures, to which reference is made in this regard. In the disclosed processes, a detachment of the substrate from the substrate mounting fixture after the removal of the fixing, in particular vacuum fixing, is of decisive importance. The fixings can in particular be the following fixings:
mechanical fixings, in particular clamps,
vacuum fixings, in particular with individually controllable vacuum tracks or vacuum tracks connected together,
electrical fixings, in particular electrostatic fixings,
magnetic fixings,
adhesive fixings.

The fixings can in particular be controlled electronically.

The vacuum fixing is the most preferred type of fixing. The vacuum fixing preferably includes a plurality of vacuum tracks, which emerge at the surface of the substrate mounting fixture. The vacuum tracks can preferably be controlled individually.

The radially symmetrical fixing/holder is either drilled vacuum holes, a circular vacuum lip or comparable vacuum elements, with the aid of which the substrate can be fixed.

In another preferred embodiment, provision is made such that the fixing elements are combined in a number of zones, wherein the zones can be switched on and off separately and/or are arranged at the outer edges of the substrates, wherein the zones are preferably arranged distributed at a uniform distance from one another at the outer edges of the substrates. Larger areas can advantageously be switched on and off by means of the zones. It is thus possible to simplify the control of the detachment or of the fixing elements. The detachment of the substrates preferably takes place controlled from the inside outwards in that the individual fixing elements are switched off from the inside outwards.

In another preferred embodiment, provision is made such that the fixing of the substrates takes place exclusively at their outer edges.

### Contacting

It is advantageously possible by means of a convex curvature for the upper substrate to be preferably curved in the direction of the lower substrate lying opposite.

In a preferred embodiment, a contacting axis runs through the centre of one of the substrates, preferably through the centres of both substrates. In the preferred embodiment, the contacting of the substrates is thus initiated in the centres of the substrates, wherein the contacting of the substrates along the contacting axis preferably takes place completely up to the outer edges of the substrates. Due to the fact that the contacting along the contacting axis takes place completely up to the outer edges of the substrates. uniaxial contacting can advantageously take place along the entire width of the substrates.

In another preferred embodiment, provision is made such that the curvatures of the two substrates take place mirror-inverted to one another. Mirror-inverted is understood to mean mirroring in respect of a plane lying between the substrates. The plane is in particular parallel to the bond plane arising after the bonding. Advantageously, particularly exact contacting is possible when both substrates are curved mirror-inverted to one another, because the substrates can then make contact exactly at the respectively raised points.

### Substrate

The substrates are preferably radially symmetrical. The substrates can have any diameter; in particular, the substrate diameter is 1 inch. 2 inches, 3 inches, 4 inches, 5 inches, 6 inches, 8 inches, 12 inches, 18 inches or greater than 18 inches.

The thickness of the substrates lies between 1 μm and 2000 μm. preferably between 10 μm and 1500 μm, more preferably between 100 μm and 1000 μm. In particular embodiments, the substrates can have rectangular shapes, or shapes diverging at least from the circular shape. A substrate is understood in particular to mean a semiconductor wafer.

### Movement Device (Actuator)

The at least one deformation device can preferably be raised and/or lowered, particularly by means of an, in particular, central bore in a substrate mounting fixture.

The upper substrate is preferably deformed.

In a first preferred embodiment, the at least one deformation device is moved by a vertical drive in a vertical relative movement to the substrate mounting fixture. The at least one deformation device is moved between a first substrate-distant parking position (P0), in which it is countersunk in particular in an opening or bore, and a second position (P1), in which it can extend to the maximum at right angles to the mounting surface.

The respective current working position PA for the application of the fluid at the rear side on the substrate lies between P0 and P1. The position of the at least one deformation device and of the fluid and the deformation of the substrate by the outflowing fluid are preferably measured by sensors and controlled by means of a control loop or control means.

The at least one deformation device is first extended in the direction of the substrate. The fluid flows out of the at least one deformation device. The at least one deformation device contacts the substrate during the bonding at the rear side not directly, but deforms the substrate via a fluid cushion which is formed by the fluid. By means of the cushion between the at least one deformation device and the substrate, point-like deformations are reduced and no forces are transferred parallel to the substrate surface onto the substrate. The fluid flow speed, the pressure and the position of the at least one deformation device are measured and controlled for a controlled deformation of the substrate.

The at least one deformation device can preferably be retracted or adjusted to an arbitrary working position PA, e.g. when the degree of the deformation has to be readjusted. In parallel with this, the pressure of the outflowing fluid can also be readjusted. The force acting on the substrate rear side can thus be controlled very precisely before, during and after the bonding process.

Once the bonding process has ended, or no further curvature or no further pressure build-up is required, the fluid supply is ended and the at least one deformation device is retracted into the opening of the substrate mounting fixture (position P0).

In particular, if the deformation has to be interrupted when necessary or if the at least one deformation device jams in the mounting fixture, the mobile deformation means is retracted in the provided bore of the substrate mounting fixture up to parking position PO. Alternatively, the at least one deformation device can be retracted or adjusted into an arbitrary working position PA. e.g. when the degree of deformation has to be readjusted.

In another embodiment, the lower and/or the upper mounting fixture, preferably the lower mounting fixture, can be moved vertically for a vertical controlled approach of the substrate surfaces of the lower and the upper substrate.

The at least one deformation device can be guided by means of the at least one movement device, for example a lifting device, through the opening. in particular a bore, in the substrate holding device in the direction of the substrate surface. If need be, a closing element, in particular a seal, enables the sealing of the opening of the substrate mounting fixture to the at least one deformation device.

The movement of the at least one deformation device between working position PA and parking position PO can take place in different ways.

In particular, the at least one deformation device can be fitted on a lever arm. The lever arm can also perform a rotational or tilting movement in another embodiment for the movement of the at least one deformation device.

The movement of the at least one deformation device is preferably controlled very precisely and carried out at different speeds. This preferably takes place at a speed in the range between 0.1 μm/s to 0.5 μm/s.

The at least one deformation device can be driven in different ways. e.g. with mechanical, electrical, hydraulic and/or pneumatic drives.

The control (x, y, z, ϑ) of the at least one deformation device can preferably be synchronised with the fluid flow.

### BRIEF DESCRIPTION OF THE DRAWINGS

Further advantages, features and details of the invention emerge from the following description of preferred examples of embodiment and with the aid of the drawings. Diagrammatically, these show in:

Figure la: a cross-sectional view of an upper substrate mounting fixture of a preferred embodiment of the device according to the invention with a deformation device in a parking position PO.

FIG. 1b: the cross-sectional view from FIG. 1a with the deformation device in a maximum extendable position PI,

Figure lc: a plan view onto a substrate mounting fixture of a preferred embodiment of the device according to the invention through a cross-section A-A.

FIG. 2a: a cross-sectional view of a preferred device according to the invention in a first process step according to an exemplary method according to the invention,

FIG. 2b: the device from FIG. 2a in a second process step after the approach of the upper and lower substrate mounting fixtures,

FIG. 2c: a cross-sectional view of the upper substrate mounting fixture in a third process step during the deformation of the upper substrate, wherein the at least one deformation device does not make direct contact with the substrate at the rear side during the bonding process, but rather deforms via a fluid cushion (detail view),

FIG. 3a: a cross-sectional view of the device according to the invention in a third process step during the deformation of the upper substrate via the fluid cushion and the central contacting of the upper with the lower substrate,

FIG. 3b: a cross-sectional view of the device according to the invention in a fourth process step during a continuous bonding wave, wherein the upper substrate is detached from the substrate mounting fixture by interrupting the vacuum fixings, wherein the at least one deformation device remains in or is readjusted into a working position.

FIG. 3c: the cross-sectional view of the device according to the invention in a fifth process step during a continuous bonding wave, wherein the upper substrate has been detached from the substrate mounting fixture by interrupting the vacuum fixings, wherein the at least one deformation device is moved back into the parking position.

FIG. 3d: a cross-sectional view of the device according to the invention in a sixth process step with a completed bonding process.

### DETAILED DESCRIPTION OF THE INVENTION

In the figures, identical components and components with the same function are denoted by the same reference numbers.

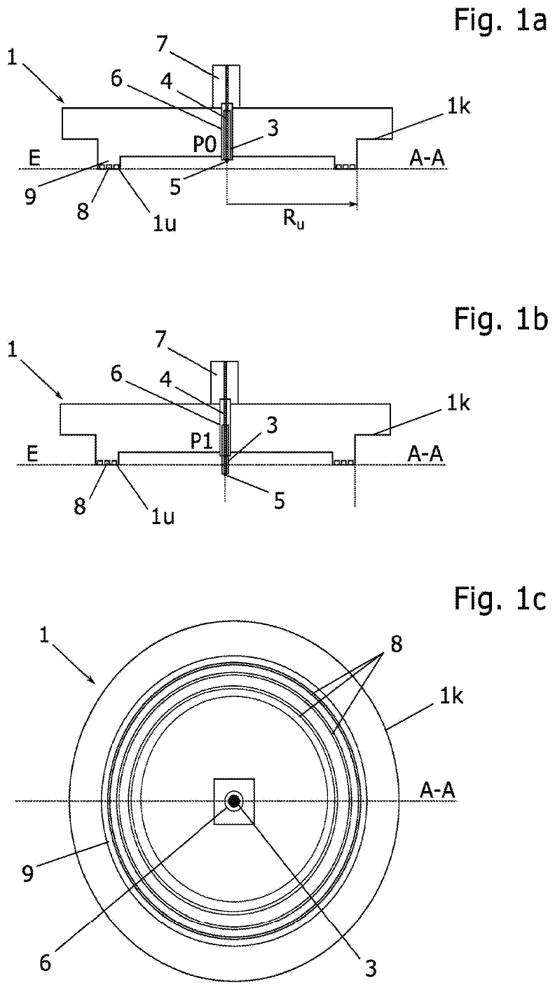

FIG. 1a shows an upper first substrate mounting fixture 1 with a mobile deformation device 3 in a parking position P0. A mounting body 1k has a structure which comprises a mounting surface 1u in a mounting plane E. Only an outer annular section 9 of mounting surface 1u is preferably provided for fixing a substrate by means of fixing elements, represented as vacuum tracks 8.

The radius of the mounting body 1k can. as shown in the embodiment according to FIG. 1a, be greater than radius Ru of mounting surface 1u, in particular an annular shoulder section set back with respect to mounting surface lu. Radius Ru of mounting surface 1u corresponds approximately to the radius of the substrates to be bonded.

Substrate mounting fixture 1 contains a central opening 6 for the feed-through of deformation device 3 with a fluid line 4 and a fluid outlet opening 5. Deformation device 3 is controlled with a movement device 7.

The device for performing the bonding process preferably comprises sensors for monitoring and controlling the substrate curvature and the bonding process (not represented in the figures). The temperature of the fluid flow and/or deformation device 3 can be regulated.

Local expansions or distortions can be reduced or minimised by controlling the temperature. Substrate mounting fixtures 1, 2 can preferably be heated and/or cooled. Temperature sensors enable the measurement and control of the temperature. The signals of the temperature sensors are fed to a temperature regulator (not represented in the figures), so that the temperature can be regulated as required. Further sensors enable the measurement and control of the flow speed, the pressure and the position of deformation device 3 for a controlled deformation of the substrate.

FIG. 1b shows a cross-sectional view of the upper substrate mounting fixture of a preferred embodiment of the device according to the invention with deformation device 3 in a maximum extendable position PI.

In a preferred embodiment, deformation device 3 comprises its own movement device 7, in particular its own vertical drive, for a vertical relative movement with respect to mounting fixture 1. Deformation device 3 is moved between a first substrate-distant parking position (PO) according to FIG. 1a, in which deformation device 3 is countersunk in the opening, and a second position (P1) according to FIG. 1b, in which deformation device 3 can be extended to the maximum at right angles to the mounting surface. Working position PA of deformation device 3 lies between PO and PI.

The control of the deformation of substrate10 preferably takes place by the continuously regulatable adjustment of the distance of deformation device 3 from substrate 10 during the deformation and/or by the pressure with which the fluid acts on substrate 10 and/or by other parameter changes.

In an independent embodiment, deformation device 3 can execute not only a vertical relative movement towards substrate mounting fixture 1 (Z-direction), but also a tilting movement with an angle 9. The X-Y plane is defined in particular by mounting plane E according to FIG. 1a and 1b.

The Z-direction lies at right angles to the X-Y plane. The device according to the invention comprises in this special embodiment a deformation device 3, which is designed to perform a movement in translation and in particular also a rotational movement (not represented in the figures).

In another embodiment, an X-Y alignment of deformation device 3 is also possible, so that, as a result of the movement (X, Y, Z, 9) of deformation device 3 coupled with a precise detection of the position of deformation device 3 with respect to the substrate, a very precise control of the deformation and thus as precise and gentle a deformation as possible of the at least one substrate for the contacting of substrates 10, 11 is achieved.

Central opening 6 for the feed-through of deformation device 3 can be seen in plan view on substrate mounting fixture 1 in FIG. 1c. In this embodiment. only an outer annular section 9 of mounting surface lu is provided for fixing the substrate by means of vacuum tracks 8.

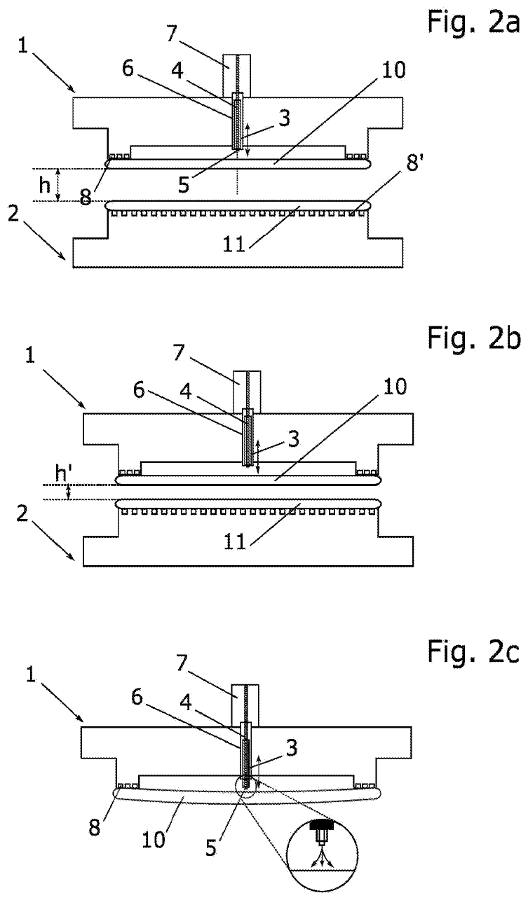

In a first process step of a first embodiment of the method according to the invention according to FIG. 2a, two substrates 10, 11—first substrate 10 positioned on first/upper substrate mounting fixture 1. second substrate 11 positioned on a second/lower substrate mounting fixture 2—are aligned and fixed by means of vacuum fixings. The feeding of substrates 10, 11 can take place manually, but preferably automatically by means of a robot.

Upper substrate mounting fixture 1 comprises a mobile deformation device 3 for the targeted, in particular controllable, deformation of upper substrate 10 with an adjustable force. Upper substrate mounting fixture 1 comprises in particular at least one opening 6 through which deformation device 3, in particular a bonding pin 3 with a fluid line 4 and a fluid outlet opening and/or a nozzle 5, can bring about a deformation of upper substrate 10. Deformation device 3 is controlled by a movement device 7.

In the embodiment according to FIG. 2a, only an outer annular section 9 of mounting surface lu is provided on upper substrate mounting fixture 1 for fixing upper substrate 10 by means of vacuum tracks, whereas lower substrate 11 on lower substrate mounting fixture 2 is fixed over the entire area 5 with vacuum tracks 8′.

Substrates 10, 11 are first adjusted extremely precisely for exact alignment and are held separated at a distance h for example during an evacuation and/or inert gas rinsing process.

In a second process step according to FIG. 2b, a relative approach of the two substrates 10, 11 in particular takes place, in particular by the relative approach of the substrate mounting fixtures. Lower substrate mounting fixture 2 is preferably raised so that lower substrate 11 actively approaches upper substrate 10. Also conceivable, however, is the active approach of upper substrate mounting fixture 1 towards lower substrate mounting fixture 2 or the simultaneous approach of both substrate mounting fixtures 1, 2 towards one another.

Distance h between upper substrate 10 and lower substrate 11 is reduced to a precisely defined distance h′. The approach of the two substrates 10, 11 takes place in particular up to a distance h′ between 1 μm and 2000 μm, preferably between 1 μm and 1000 μm, still more preferably between 5 μm and 200 μm, most preferably between 10 μm and 100 μm. Distance h, h′is defined as the smallest vertical distance between two surface points of substrates 10, 11.

The overlay error is particularly dependent on the distance or gap between the two substrates 10, 11 immediately before the start of the bonding process. Insofar as substrate 10 is deformed by deformation device 3 with a first controllable force. the distance between the substrates is a function of the location.

In particular, the distance between the substrates is greatest at the edge. The minimum distance is located in the region of the convex maximum of deformed substrate 10. The shape of a deformed substrate thus also has an influence on the overlay error.

The distance between the substrates at the edge immediately before bonding is set in particular to less than 5 mm. preferably less than 2mm, still more preferably less than 1 mm. most preferably less than 0.5 mm, with utmost preference less than 0.1 mm. The distance between the substrates beneath the convex maximum immediately before bonding is in particular set to less than 1 mm, preferably less than 100 μm, still more preferably less than 30 μm. This distance is preferably set to between 10 and 20 μm.

In a third process step according to FIG. 2c, deformation device 3 with fluid line 4 influences the rear side of upper substrate 10 via a fluid cushion and generates a deformation, in particular a sag referred to as concave from the side of deformation device 3 (i.e. from above). Deformation device 3 acts on upper substrate 10 in particular with a first adjustable force of more than 1 mN, preferably more than 10 mN, still more preferably more than 50mN. most preferably more than 100 mN. but in particular less than 5000 mN.

The force is too small to detach substrate 10 from substrate mounting fixture 1, but strong enough to generate the desired sag. By means of the controllable fluid cushion between deformation device 3 and the substrate, point-like deformations are reduced and no forces are transferred parallel to the substrate surface onto the substrate.

By means of the fluid cushion, in particular an N2 gas cushion, between deformation device 3 and substrate 10, no forces are transferred parallel to the substrate surface onto the substrate and the contact surface becomes greater, so that local substrate deformations are reduced. Parameters such as pressure. temperature, force and speed are measured as required with suitable measurement methods and/or with sensors and can be regulated and controlled separately. The sensors include for example flow speed sensors and for deformation device 3 position sensors (not represented in the figures).

Before bonding or prebonding or contacting, substrates 10. 11 can as required the heated by heating means and/or cooled by cooling means, i.e. temperature-regulated (not represented).

The sequence of the second and third process steps is not essential and the latter can also be carried out in the reverse order.

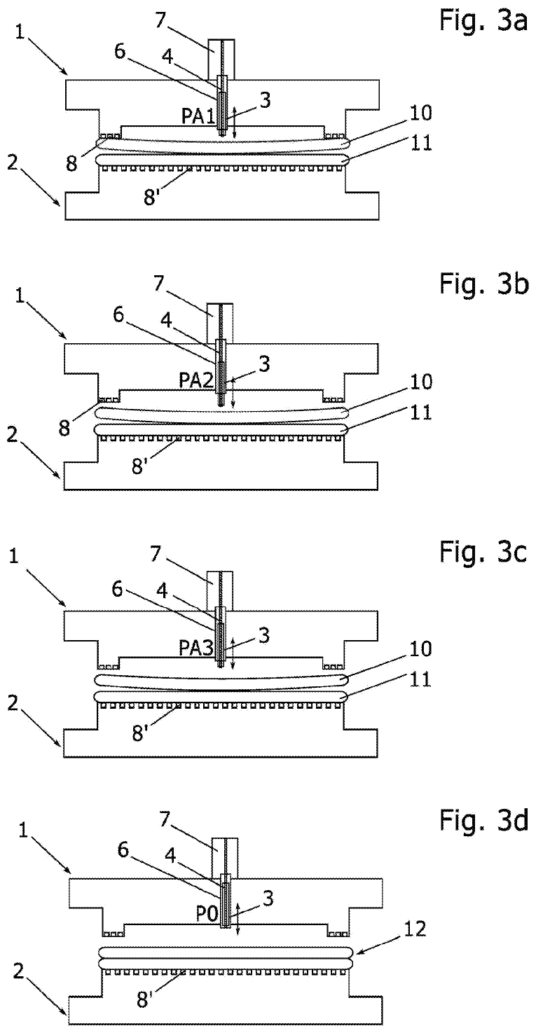

In a fourth process step, a further force application on substrate 10 takes place according to FIG. 3a. In a first procedure according to the invention, substrate 10 is acted upon with a second adjustable force by increasing the fluid pressure. A point-like central contacting of upper substrate 10 with lower substrate 11 is thus brought about.

The gas pressure lies between 0.01 bar and 8 bar.

Alternatively, a mounting fixture 2 can also be moved upwards in the Z-direction instead of or in addition to a further approach of deformation device 3 and/or a controlled increase of the fluid pressure, so that a further increase in pressure or approach of the substrate surfaces occurs.

Deformation device 3 is moved between a first substrate-distant parking position (P0), in which deformation device 3 is countersunk into opening 6, and a second position (P1), in which the deformation device can be extended to the maximum at right angles to the mounting surface. Respective current working position PA for the application of the fluid flow at the rear side onto substrate 10 lies between P0 and P1. The position of deformation device 3 and/or of the fluid flow and/or the deformation of substrate 10 are preferably measured by sensors and controlled by means of a control loop and control means.

Monitoring of the propagation of the continuous bonding wave in particular takes place.

FIGS. 3b and 3c show a change in the position of deformation device 3 from working position PA2 in FIG. 3b to working position PA3 in FIG. 3c.

As a result of controlling and changing the position of deformation device 3 and/or the fluid pressure, a deformation of upper substrate 10 as gentle as possible can take place and controlled contacting and control of the propagation of the bonding wave can take place. The controlled change in the position of the deformation device and/or of the fluid pressure can be regulated after the contacting and during the propagation of the bonding wave or during the targeted removal of fixing 8 of substrate 10.

In a fifth process step according to FIG. 3b, switching-off of fixing 8 of upper substrate mounting fixture 1 in particular takes place. It would also be conceivable for upper substrate 10 to be released by a targeted removal of fixing 8. Particularly in the case of vacuum fixings, which include a plurality of individually controllable vacuum tracks, the targeted removal of the fixing takes place by a continuous removal of the vacuum, in particular from the centre to the edge. The process step is initiated in particular at a time at which one of the parameters of the measurement means reaches a predetermined/set or settable value.

After the detachment of the deformed substrate 10 (in the direction of substrate 11 lying opposite) which has sagged according to FIGS. 3b and 3c. a continuous and uniform, in particular at least predominantly independent connection along the bonding front, associated with minimum force and therefore with minimum distortion. takes place as a result of the advance of a bonding wave. Upper substrate 10 is subject, after the initiation of the bond at a bond initiation point and after the detachment, to no additional fixing, i.e. can move freely apart from the fixing at the bond initiation point.

After the detachment of the deformed substrate 10 (in the direction of substrate 11 lying opposite) which has sagged, the bonding wave can be controlled particularly preferably with regard to its speed. The control of the speed takes place in particular indirectly via the composition and/or the density and/or the temperature of a gas in the atmosphere in which the bonding takes place.

Although the method according to the invention should preferably take place in a low-pressure atmosphere, preferably in a vacuum, it may be advantageous to carry out the bonding process in another atmosphere. As a result of the point-like contact according to the embodiment in FIG. 3b or 3c, the bonding wave during bonding runs radially symmetrically from the centre to the side edge and in this process pushes an annular gas cushion in front of it.

Due to the great force, inclusions of gas bubbles are prevented. Upper substrate 10 thus lies in a preferred embodiment on a kind of gas cushion during the bonding process. By selecting a gas or gas mixture, it is established how quickly and how intensely upper substrate 10 can be lowered and/or stretched. In addition, the speed of the bonding wave can be controlled by the properties of the gas or gas mixture. It is conceivable according to the invention for the atmosphere to control the bonding speed by the selection of the gas or the gas mixture and the pressure and/or the temperature.

In a sixth process step according to FIG. 3d, the use of deformation device 3 is stopped. The fluid flow is interrupted and deformation device 3 is retracted. Deformation device 3 is retracted in the provided opening of substrate mounting fixture 1, for example up to parking position PO. This process step is initiated in particular at a time at which one of the parameters of the measurement means reaches a predetermined/set or settable value.

Finally, the substrate stack can be removed after switching-off of lower fixing means 8′ by gripping with a robot arm (not represented) from lower substrate mounting fixture 2 or from the bonding device.

### List of Reference Numbers

1, 2 substrate mounting fixture
1k mounting body
1u mounting surface
3 deformation device
4 fluid line
5 nozzle
6 opening
7 movement device
8, 8′ fixing means
9 annular section
10, 11 substrate
12 substrate stack
P0 parking position
P1 maximum extendable position
PAI, PA2, PA3 working position
E mounting plane
h, h′ distance
Ru circular radius
A-A cross-sectional line

1-15. canceled.

16. A device for bonding a first substrate with a second substrate, comprising:
at least one deformation device for deforming at least one of the first substrate and the second substrate by means of a fluid that acts on at least one of the first substrate and the second substrate, the at least one deformation device being mobile and comprising a mobile nozzle.

17. The device according to claim 1, wherein the at least one deformation device comprises a mobile hollow pin, and
wherein the pin comprises a central axial bore.

18. The device according to claim 1, wherein the at least one deformation device comprises a mobile hose.

19. The device according to claim 1, further comprising:
at least one movement device for moving the at least one deformation device.

20. The device according to claim 1, wherein the at least one deformation device is arranged in an opening of a substrate mounting fixture.

21. The device according to claim 1, wherein the at least one deformation device is mobile normal to a mounting plane of a substrate mounting fixture.

22. The device according to claim 1, wherein the at least one deformation device is designed to occupy at least one parking position and a working position.

23. The device according to claim 1, wherein the at least one deformation device is arranged in a parking position completely in an opening of a substrate mounting fixture.

24. The device according to claim 1, wherein the at least one deformation device projects in a maximum position beyond a mounting plane of a substrate mounting fixture.

25. A method for bonding a first substrate with a second substrate comprising:
deforming, using at least one deformation device, at least one of the first substrate and the second substrate by means of a fluid that acts on at least one of the first substrate and the second substrate.

26. The method according to claim 10, wherein the at least one deformation device is mobile normal to the mounting plane of a substrate mounting fixture.

27. The method according to claim 10, wherein the at least one deformation device occupies at least one parking position and a working position.

28. The method according to claim 10, wherein the at least one deformation device is arranged in a parking position completely in an opening of a substrate mounting fixture.

29. The method according to claim 10, wherein the at least one deformation device projects in a maximum position beyond a mounting plane of a substrate mounting fixture.
